(19) United States
(12) Patent Application Publication
(10) Pub. No.: US 2026/0244795 A1
(43) Pub. Date: Aug. 20, 2026

(54) DYNAMIC MOLD CREATION

(71) Applicant: INTERNATIONAL BUSINESS MACHINES CORPORATION, Armonk, NY (US)

(72) Inventors: Tushar Agrawal, West Fargo, ND (US); Martin G. Keen, Cary, NC (US); Carolina Garcia Delgado, Zapopan (MX); Sarbajit Kumar Rakshit, Kolkata (IN)

(21) Appl. No.: 19/054,226

(22) Filed: Feb. 14, 2025

(51) Int. Cl. G06F 30/12; G06F 30/27

(52) U.S. Cl. CPC G06F 30/12; G06F 30/27

(57) ABSTRACT

Embodiments determine that a snake robot is to be utilized based on performing a cost benefit analysis on a design structure using a trained artificial intelligence (AI) model; determine spatial patterns and design details of the design structure based on analyzing the design structure by utilizing a first convolutional neural network (CNN) model; dynamically determine a configuration mold based on the determined spatial patterns and the determined design details of the design structure; create a mold by commanding the snake robot to wrap around a physical representation of the design structure; create a molded object by perform pouring of liquid material into the created mold; and command detachment of the snake robot from the molded object in response to a predetermined solidification level of the poured liquid material into the molded object being achieved.

### BACKGROUND

Aspects of the present invention relate generally to a system and a method for dynamic mold creation.

Snake robots represent an evolving field of robotics. In particular, snake robots mimic a serpentine movement of snakes. Accordingly, snake robots navigate complex environments. Snake robots can also be referred to as serpentine robots or snake-like robots.

### SUMMARY

In a first aspect of the invention, there is a computer-implemented method including: determining that a snake robot is to be utilized based on performing a cost benefit analysis on a design structure using a trained artificial intelligence (AI) model; determining spatial patterns and design details of the design structure based on analyzing the design structure by utilizing a first convolutional neural network (CNN) model; dynamically determine a configuration mold based on the determined spatial patterns and the determined design details of the design structure; creating a mold by commanding the snake robot to wrap around a physical representation of the design structure; creating a molded object by perform pouring of liquid material into the created mold; and commanding detachment of the snake robot from the molded object in response to a predetermined solidification level of the poured liquid material into the molded object being achieved.

In another aspect of the invention, there is a computer program product including one or more computer readable storage media and program instructions stored on the one or more computer readable storage media to perform operations including: receiving a design structure from an external application; determining that a snake robot is to be utilized based on performing a cost benefit analysis on the design structure using a trained artificial intelligence (AI) model; determining spatial patterns and design details of the design structure by analyzing the design structure by utilizing a first convolutional neural network (CNN) model; dynamically determining a configuration mold based on the determined spatial patterns and the determined design details of the design structure; creating a mold by commanding the snake robot to wrap around a physical representation of the design structure; creating a molded object by performing pouring of liquid material into the created mold; and commanding detachment of the snake robot from the molded object in response to a predetermined solidification level of the poured liquid material into the molded object being achieved.

In another aspect of the invention, there is a system including a processor set, one or more computer readable storage media, and program instructions stored on the one or more computer readable storage media to cause the processor set to perform operations including: receiving a design structure from an external application; determining that a snake robot is to be utilized based on performing a cost benefit analysis on the design structure using a trained artificial intelligence (AI) model; determining spatial patterns and design details of the design structure based on analyzing the design structure by utilizing a first convolutional neural network (CNN) model; dynamically determining a configuration mold based on the determined spatial patterns and the determined design details of the design structure; creating a mold by commanding the snake robot to wrap around a physical representation of the design structure; creating a molded object by performing pouring of liquid material into the created mold; commanding detachment of the snake robot from the molded object in response to a predetermined solidification level of the poured liquid material into the molded object being achieved; and performing a final analysis of the molded object after detachment of the snake robot using a second CNN model which is different from the first CNN model.

### BRIEF DESCRIPTION OF THE DRAWINGS

Aspects of the present invention are described in the detailed description which follows, in reference to the noted plurality of drawings by way of non-limiting examples of exemplary embodiments of the present invention.

FIG. 1 depicts a computing environment according to an embodiment of the present invention.

FIG. 2 shows a block diagram of an exemplary environment in accordance with aspects of the present invention.

FIG. 3 shows a diagram of a snake robot with a mold in accordance with aspects of the present invention.

FIG. 4 shows another diagram of the snake robot with the mold in accordance with aspects of the present invention.

FIG. 5 shows a flowchart of an exemplary method in accordance with aspects of the present invention.

FIG. 6 shows a flowchart of an exemplary method in accordance with aspects of the present invention.

FIG. 7 shows a flowchart of an exemplary method in accordance with aspects of the present invention.

### DETAILED DESCRIPTION

Aspects of the present invention relate generally to a system and a method for dynamic mold creation. Various embodiments involve causing a snake robot to wrap around a design structure to create a mold into which liquid 3D printing material is poured. In embodiments the material in the mold solidifies to form a molded object and the snake robot is detached from the molded object. In this manner, implementations of the invention provide a faster and more cost-effective manufacturing process than conventional 3D printing processes, which involve building layers on top of each other to create a 3D object.

Embodiments of the present invention provide a system, a computer program product, and a computer-implemented method for utilizing a snake robot to dynamically create a helical profile with varying cross-sectional areas. In particular, aspects of the present invention provide a system, a computer program product, and a computer-implemented method to expedite a three-dimensional (3D) printing process by pouring liquid material into the helical profile and eliminating the need for separate molds for different cross-sectional profiles. In further aspects of the present invention, the system, the computer program product, and the computer-implemented method perform cost benefit analysis between mold creation with snake robots and 3D printing. Embodiments of the present invention provide a snake robot computing system which creates a helical mold wrapped with at least one snake robot to facilitate liquid pouring on the helical mold to create a desired mold structure. In further embodiments, the snake robot computing system creates a wrapping shape of the at least one snake robot with the helical mold to facilitate liquid pouring. In further aspects of the present invention, the snake robot computing system creates a swarm snake robot collaboration by utilizing a plurality of snake robots with a predetermined combined running length for wrapping around the helical mold.

Embodiments of the present invention analyze a cross-sectional area profile of an initial physical structure and determine a force needed to ensure a structure stability of a snake robot created mold. Accordingly, embodiments calculate a first portion of a snake robot that should wrap around the initial physical structure and a second portion of the snake robot that is used to create a mold. Embodiments of the present invention provide stability and effective mold creation by strategically allocating the first and second portions of the snake robot. Embodiments of the present invention determine an appropriate pouring of liquid material (e.g., an appropriate time period for pouring the liquid material) on the snake robot created mold. In particular, embodiments of the present invention detach the snake robot from the solidified mold structure in response to a predetermined solidification occurring on the mold structure. In aspects of the present invention, the system, the computer program product, and computer-implemented method allow the snake robot to move upwards on the solidified mold structure in response to the snake robot detaching from the solidified mold structure. Accordingly, implementations of the present invention provide a final desired structure with a predetermined height.

Aspects of the present invention determine a number of snake robots that are combined to create a predetermined running length based on a shape, profile, and height of the final desired structure. Further embodiments of the present invention adjust the number of snake robots (e.g., increase or decrease the number of snake robots) based on a change in the shape, profile, and the height of the final desired structure. In aspects of the present invention, the system, the computer program product, and the computer-implemented method combine a plurality of snake robots to create a chain of snake robots with the predetermined running length for wrapping around a mold structure.

Embodiments of the present invention determine a number of layers of a mold that are created based on a weight of liquid material that is going to be poured onto the mold, a weight of the mold, and a strength of a snake robot that is wrapped around the mold. For example, embodiments determine that a single layer of the mold is needed based on a large weight of liquid material and high strength of the snake robot. In another example, embodiments determine that multiple layers of the mold are needed based on a small weight of liquid material and low strength of the snake robot.

Aspects of the present invention create a shape for a helical profile of the snake robot based on a shape of the final desired structure. In embodiments, the shape of the final desired structure can be at least one of cylindrical, conical, rectangular, etc. Embodiments of the present invention utilize 3D printing to provide surface finish of the final desired structure

Embodiments of the present invention provide a computer-implemented method, a system, and a computer program product for dynamically creating a helical profile with varying cross-sectional areas using at least one snake robot. In contrast, conventional systems typically manufacture molds using only 3D printing, which is a slow process since the material of the mold is created in a layer by layer process. Further, conventional systems utilize 3D printing to create a separate mold for each cross-sectional profile. Accordingly, conventional systems have limitations which prevent dynamic and efficient mold creation for varying cross-sectional areas.

Embodiments of the present invention include a system, method, and computer program product for dynamically creating molds for different cross-sectional areas by utilizing at least one snake robot. Accordingly, implementations of the present invention provide an improvement (i.e., technical solution) to a problem arising in the technical field of mold creation. In particular, embodiments of the present invention dynamically create molds based on an initial design structure. Further, embodiments of the present invention dynamically create the molds for structural stability using artificial intelligence (AI) algorithms for optimizing a cost-benefit analysis.

Implementations of the present invention are necessarily rooted in computer technology. For example, the steps of performing a cost benefit analysis on the design structure using a trained artificial intelligence (AI) model to determine that a snake robot is to be utilized; and analyzing the design structure by utilizing a first convolutional neural network (CNN) model to determine spatial patterns and design details of the design structure cannot be performed in the human mind (or with pen and paper). Performing a cost benefit analysis on a design structure using a trained AI model and analyzing the design structure by utilizing a CNN is, by definition, performed by a computer and cannot be performed in the human mind (or with a pen and paper) due to the complexity and amounts of calculations involved in the dynamic mold creation system. In further embodiments, the steps of performing a final analysis of the configuration mold after detachment of the snake robot using a second CNN model; and determining discrepancies between the configuration mold and a predicted mold using a long short-term memory (LSTM) model are also rooted in computer technology and cannot be performed in the human mind (or with pen and paper).

Aspects of the present invention include a method, system, and computer program product for dynamically creating a mold structure using at least one snake robot. For example, a computer-implemented method includes: creating a swarm snake robot collaboration with at least one snake robot to achieve a predetermined combined running length; creating a wrapping shape of the swarm snake robot collaboration around a helical mold to allow pouring of liquid material; creating a final design structure in response to the liquid material being poured on the wrapping shape of the swarm snake robot collaboration around the helical mold; and perform surface finish on the final design structure. In further embodiments, the computer-implemented method performs the surface finish on the final design structure using three-dimensional printing. Aspects of the present invention analyze a cross-sectional profile, determine a force needed to ensure structural stability of the wrapping shape of the swarm snake robot collaboration around the helical mold, and calculate a first portion of the swarm snake robot collaboration that should wrap around the helical mold and a second portion of the swarm snake robot collaboration that will create the final design structure. Embodiments of the present invention collaborate the at least one snake robot wrapped around a target area of the helical mold with a liquid material pouring module to determine a time period for pouring the liquid material on the swarm snake robot collaboration that is wrapped around the helical mold. In further embodiments of the present invention, the snake robot detaches from the solidified mold after the liquid material has been poured. In aspects of the present invention, the snake robot moves upward after detachment from the solidified mold. Embodiments of the present invention collaborate to select the predetermined combined running length based on adding or removing a number of robot snakes based on a shape, profile, and height of the final design structure. Aspects of the present invention calculate a number of layers of the initial mold that are utilized with the at least one snake robot to create the final design structure.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as dynamic mold creation code of block 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

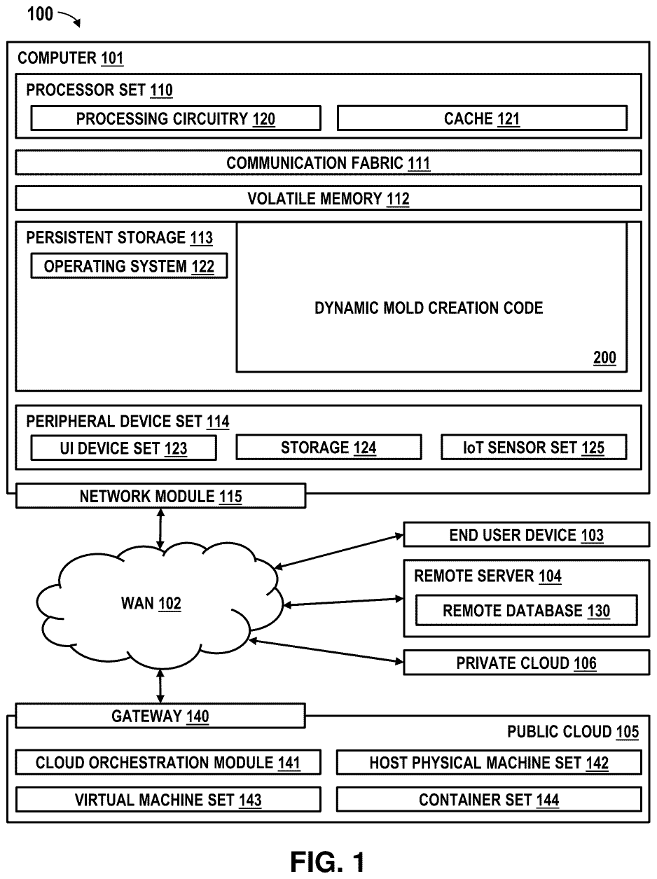

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

CLOUD COMPUTING SERVICES AND/OR MICROSERVICES (not Separately Shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

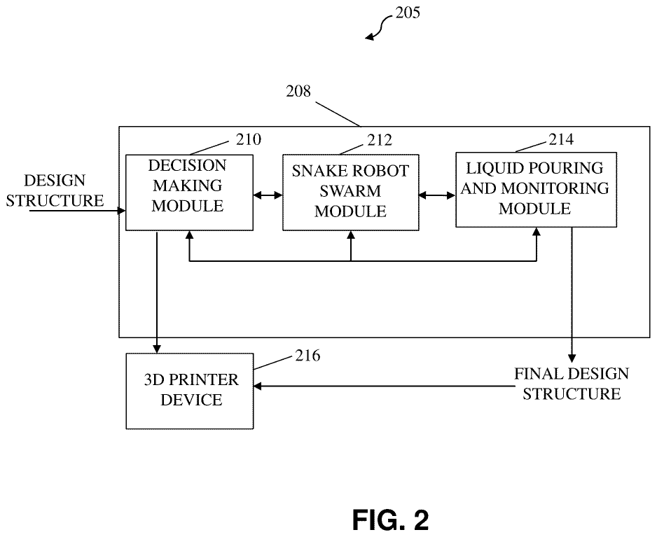

FIG. 2 shows a block diagram of an exemplary environment 205 in accordance with aspects of the present invention. In embodiments, the environment 205 includes a dynamic mold creation server 208, which may comprise one or more instances of the computer 101 of FIG. 1. In other examples, the dynamic mold creation server 208 comprises one or more virtual machines or one or more containers running on one or more instances of the computer 101 of FIG. 1. The environment 205 may also include a 3D printer device 216 which is external to the dynamic mold creation server 208 and may be included in at least one external server, such as one or more instances of the remote server 104 of FIG. 1.

In embodiments, the dynamic mold creation server 208 of FIG. 2 comprises a decision making module 210, a snake robot swarm module 212, and a liquid pouring and monitoring module 214, each of which may comprise modules of the code of block 200 of FIG. 1. Such modules may include routines, programs, objects, components, logic, data structures, and so on that perform particular tasks or implement particular data types that the code of block 200 uses to carry out the functions and/or methodologies of embodiments of the present invention as described herein. These modules of the code of block 200 are executable by the processing circuitry 120 of FIG. 1 to perform the inventive methods as described herein. The dynamic mold creation server 208 may include additional or fewer modules than those shown in FIG. 2. In embodiments, separate modules may be integrated into a single module. Additionally, or alternatively, a single module may be implemented as multiple modules. Moreover, the quantity of devices and/or networks in the environment is not limited to what is shown in FIG. 2. In practice, the environment may include additional devices and/or networks; fewer devices and/or networks; different devices and/or networks; or differently arranged devices and/or networks than illustrated in FIG. 2.

In embodiments, the decision making module 210 receives a design structure from an external application. In aspects of the present invention, the design structure is a structure of a design in which complex objects are broken down into individual components. In further embodiments, the external application comprises a computer aided design (CAD) application. In embodiments of the present invention, the CAD application interprets and visualizes 3D structures, such as the design structure. In aspects of the present invention, the decision making module 210 performs a cost benefit analysis of the design structure to determine whether to create a final design structure using a snake robot process or create the final design structure using a 3D printer.

In further embodiments, the decision making module 210 performs the cost benefit analysis by utilizing a trained artificial intelligence (AI) model to determine whether to create the final design structure using the snake robot process or create the final design structure using the 3D printer. In further embodiments, the AI model is trained using historical time data to create a historical design structure using 3D printing, historical time data to create the historical design structure using a snake robot, historical cost data to create the historical design using 3D printing, historical cost data to create the historical design using the snake robot, historical material usage data to create the historical design using 3D printing, and historical material usage date to create the historical design using the snake robot. Accordingly, the trained AI model outputs a determination whether to create the final design structure using the snake robot process or the 3D printer using historical data of time, cost, and material usage. In further embodiments, the AI model is continuously trained on real-time feedback data to improve accuracy of the determination of whether to create the final design structure using the snake robot process of the 3D printer. In aspects of the present invention, the AI model is trained using at least one of a decision tree algorithm, a particle swarm optimization algorithm, gradient descent algorithm, etc. However, embodiments are not limited to these examples such that the AI model can be trained using other algorithms suitable for performing the cost-benefit analysis. The decision making module 210 also determines structural stability characteristics of the design structure and sends the determined structural stability characteristics to the snake robot swarm module 212.

In aspects of the present invention, the decision making module 210 sends a 3D printing command and the design structure to the 3D printer device 216 in response to the decision making module 210 performing the cost benefit analysis of the design structure and determining to create the final design structure using the 3D printer. In this scenario, the 3D printer device 216 performs 3D printing of the final design structure by utilizing a 3D printer. In further embodiments, the 3D printer device 216 comprises the 3D printer.

In further aspects of the present invention, the decision making module 210 sends a snake robot command and the design structure to the snake robot swarm module 212 in response to the decision making module 212 performing the cost benefit analysis of the design structure and determining to create the final design structure using the snake robot process. In this scenario, the snake robot swarm module 212 analyzes the design structure by utilizing a first convolutional neural network (CNN) model to determine spatial patterns and design details of the design structure for dynamically configuring at least one snake robot. In further embodiments, the first CNN model is trained using historical images for determining the spatial patterns and design details of the design structure. The snake robot swarm module 212 dynamically configures the at least one snake robot using the determined spatial patterns and the design details (e.g., cross-sectional area profile, height, etc.) from the first CNN model. In particular, the snake robot swarm module 212 dynamically configures a formation, a number of snake robots, a shape, a length, a wrapping pattern, etc., of the at least one snake robot using the determined spatial patterns and the design details from the first CNN model. In a specific example, the snake robot swarm module 212 dynamically configures an array of interconnected, flexible, and modular snake robots that are configured to wrap around structures to from molds of varying shapes, sizes, and helical profiles. In further embodiments, the snake robot swarm module 212 determines a configuration mold based on the cost benefit analysis of the design structure (e.g., the design details of the design structure). In aspects of the present invention, the configuration mold comprises a formation, a number of snake robots, a shape, a length, a wrapping pattern, etc.

In embodiments of the present invention, the snake robot swarm module 212 commands the at least one snake robot to perform a wrapping pattern (e.g. single layer wrapping, multi-layer wrapping, etc.) around a physical representation of the design structure to create a mold. In further embodiments, the snake robot swarm module 212 utilizes a long short-term memory (LSTM) model for determining discrepancies between a predicted molded object and the actual molded object. In aspects of the present invention, the LSTM model can be continuously trained with training data to minimize the discrepancies between the predicted molded object and the actual molded object in real-time. In aspects of the present invention, the snake robot swarm module 212 utilizes the LSTM model as a real-time feedback mechanism for minimized the discrepancies between the predicted molded object and the actual molded object. In embodiments of the present invention, the snake robot swarm module 212 sends a liquid command signal to the liquid pouring and monitoring module 214 in response to the snake robot swarm module 212 minimizing the discrepancies between the predicted molded object and the actual molded object.

In aspects of the present invention, the liquid pouring and monitoring module 214 initiates a pouring of liquid material into the created mold (i.e., the mold created by wrapping the at least one snake robot around the physical representation of the design structure) to create a molded object using the 3D printer 216 in response to receiving the liquid command signal. In an example, the 3D printer 216 uses a liquefier head with a nozzle to pour the liquid into the created mold to create the molded object. In further embodiments, the liquid pouring and monitoring module 214 regulates a flow rate and volume of the liquid material using a proportional integral derivative (PID) controller with the 3D printer 216 for providing consistency in filling the created mold. In addition, the liquid pouring and monitoring module 214 utilizes at least one sensor to monitor and predict a solidification state of the liquid material into the molded object. In further embodiments, the liquid pouring and monitoring module 214 utilizes the at least one sensor to monitor and determine an optimal time for the solidification state of the liquid material into the created mold to achieve a predetermined solidification level of the molded object. In further embodiments, the predetermined solidification level of the molded object can be determined by an administrator and corresponds with a hardened solidification level (e.g., the entire liquid material becomes completely hardened).

In embodiments of the present invention, the liquid pouring and monitoring module 214 sends an unwrap signal to the snake robot swarm module 212 in response to the liquid pouring and monitoring module 214 determining that the solidification state of the liquid material in the molded object achieves the predetermined solidification level. In this scenario, the snake robot swarm module 212 communicates with the at least one snake robot to detach from the molded object having the predetermined solidification level. In further embodiments, the at least one snake robot completely detaches which frees the molded object having the predetermined solidification level. The liquid pouring and monitoring module 214 then sends the final design structure (i.e., the molded object having the predetermined solidification level without the at least one snake robot) to the decision making module 210. The liquid pouring and monitoring module 210 also outputs the final design structure to the 3D printer device 216 (as shown in FIG. 2).

In aspects of the present invention, the decision making module 210 receives the final design structure and performs a final analysis using a second CNN model to compare the final design structure with a desired design. In particular, the decision making module 210 utilizes the second CNN model to determine spatial patterns and design details of the final design structure and compares the determined spatial patterns and design details of the final design structure with spatial patterns and design details of the desired design. In further embodiments, the second CNN model is trained using historical designs for determining the spatial patterns and design details of the design structure. Accordingly, the decision making module 210 utilizes the second CNN model to ensure quality control of the final design structure. The decision making module 210 then stores a feedback signal resulting from the comparison of the determined spatial patterns and design details of the final design structure with the spatial patterns and the design details of the desired design in a feedback database for continuous system improvement in real-time. The decision making module 210 also sends the feedback signal to the snake robot swarm module 212 and the liquid pouring and monitoring module 214 for continuous system improvement in real-time.

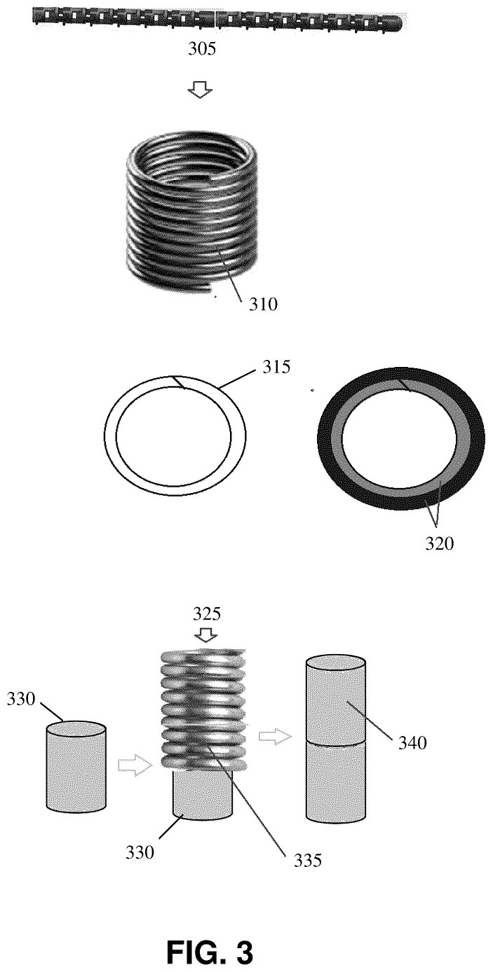

FIG. 3 shows a block diagram of a snake robot with a mold in accordance with aspects of the present invention. In FIG. 3, at least one snake robot 305 comprises a plurality of interconnected snake robots with a predetermined combined running length for wrapping around a physical representation of the design structure to create a mold. In FIG. 3, the at least one snake robot 305 is wrapped in a helical style 310 for wrapping around the physical representation of the design structure to create the mold. In embodiments, FIG. 3 shows a top view 315 of the at least one snake robot 305 wrapped in the helical style 310 for creating the mold. In further embodiments, two snake robots 320 have wrapped together to provide greater strength for creating the mold. In aspects of the present invention, a partial portion 335 of the at least one snake robot 305 is wrapped around a physical design structure 330. In further embodiments, liquid material is poured into the partial portion 335 of the at least one snake robot 305 which is wrapped around the physical design structure 330 to create a mold object 340 from the created mold. In aspects of the present invention, the liquid material is solidified to create the molded object 340 from the created mold.

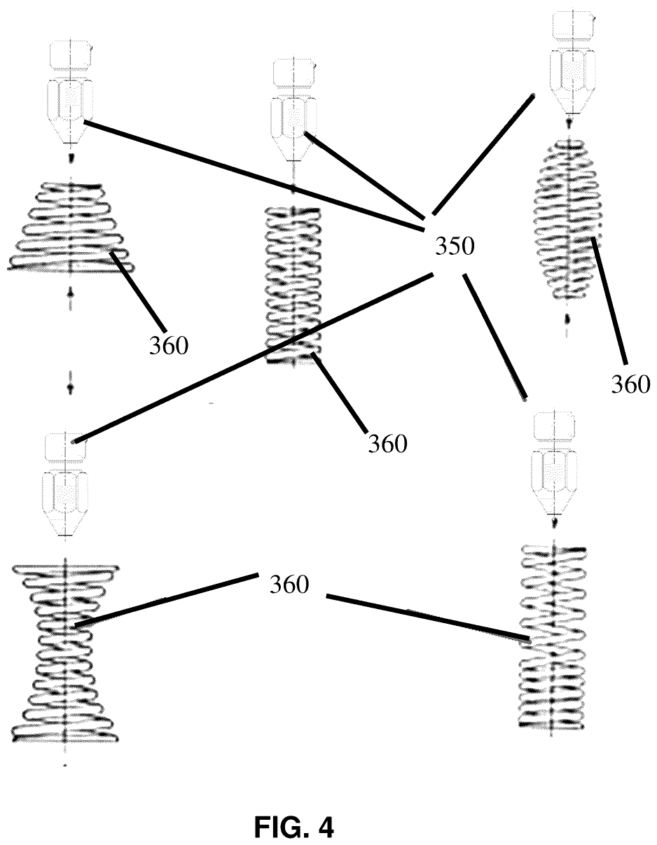

FIG. 4 shows another block diagram of the snake robot with the mold in accordance with aspects of the present invention. In FIG. 4, a 3D printing module 350 (e.g., an instance of the 3D printer device 216) pours liquid material into the at least one snake robot 305 wrapped in a helical style 360 around the physical design structure 330 (as shown in FIG. 3). As shown in FIG. 4, the helical style 360 comprises different types of helical wrappings.

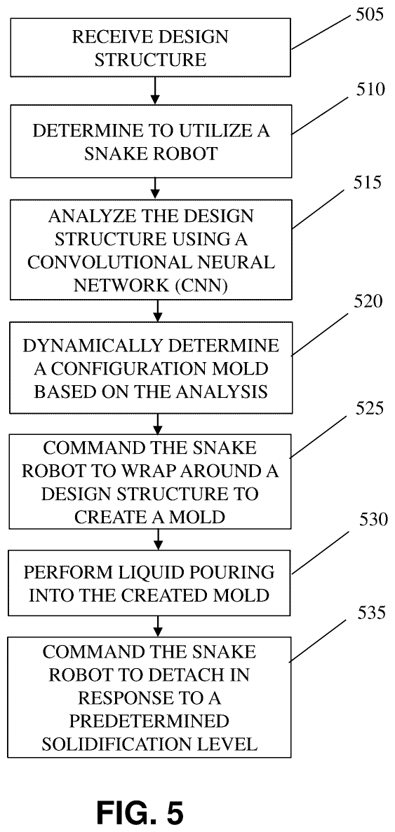

FIG. 5 shows a flowchart of an exemplary method in accordance with aspects of the present invention. Steps of the method may be carried out as operations in the environment 205 of FIG. 2 and are described with reference to elements depicted in FIG. 2.

At step 505, the system receives, at the decision making module 210, a design structure from an external application. In embodiments and as described with FIG. 2, the external application comprises a computer aided design (CAD) application. At step 510, the system determines, at the decision making module 210, utilization of a snake robot for creating a final design structure based on a cost benefit analysis. In embodiments and as described with FIG. 2, the decision making module 210 performs the cost benefit analysis using a trained artificial intelligence (AI) model.

At step 515, the system analyzes, at the snake robot swarm module 212, the design structure by using a first conventional neural network (CNN). In embodiments and as described with FIG. 2, the snake robot swarm module 212 analyzes the design structure by using a first CNN to determine the spatial patterns and design details of the design structure. At step 520, the system dynamically determines, at the snake robot swarm module 212, a configuration mold based on the analysis of the design structure. In embodiments and as described with FIG. 2, the configuration mold comprises a formation, a number of snake robots, a shape, a length, a wrapping pattern, etc.

At step 525, the system commands, at the snake robot swarm module 212, the snake robot to perform a wrapping pattern around the physical design structure 330 to create a mold. At step 530, the system performs, at the liquid pouring and monitoring module 214, a pouring of liquid material into the created mold to create a molded object. In embodiments and as described in FIG. 2, the liquid pouring and monitoring module 214 utilizes at least one sensor to monitor and determine an optimal time for a solidification state of the liquid material into the created mold to achieve a predetermined solidification level of the molded object.

At step 535, the system commands, at the snake robot swarm module 212, the snake robot to detach from the molded object in response to the solidification state of the liquid material into the molded object achieving the predetermined solidification level.

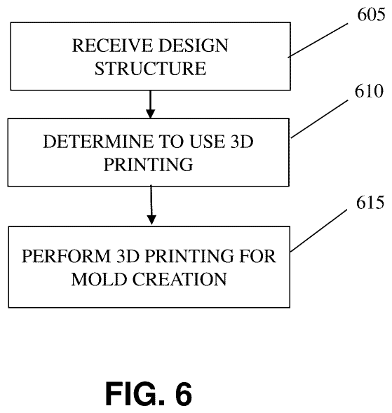

FIG. 6 shows a flowchart of an exemplary method in accordance with aspects of the present invention. Steps of the method may be carried out as operations in the environment 205 of FIG. 2 and are described with reference to elements depicted in FIG. 2.

At step 605, the system receives, at the decision making module 210, a design structure from an external application. In embodiments and as described with FIG. 2, the external application comprises a computer aided design (CAD) application. At step 610, the system determines, at the decision making module 210, to use 3D printing for creating a final design structure based on a cost benefit analysis. In embodiments and as described with FIG. 2, the decision making module 210 performs the cost benefit analysis using a trained artificial intelligence (AI) model.

At step 615, the system performs, at the 3D printer device 216, 3D printing for mold creation. In embodiments and as described with FIG. 2, the 3D printer device 216 performs the 3D printing by an external 3D printer.

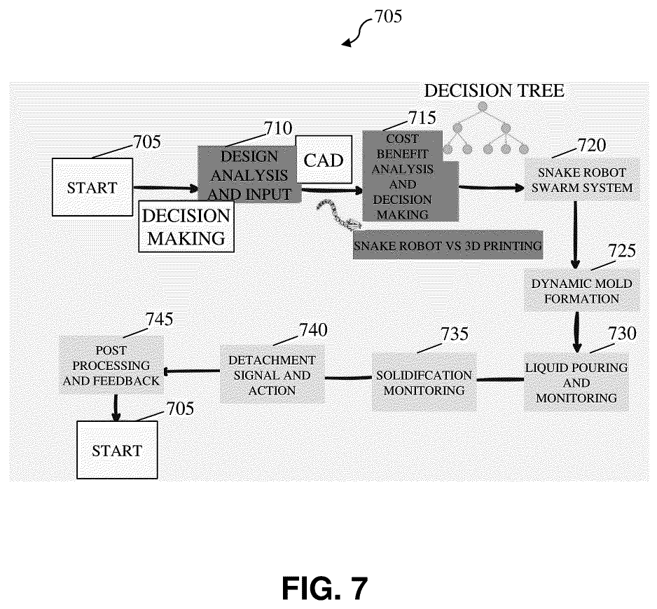

FIG. 7 shows a flowchart of an exemplary method in accordance with aspects of the present invention. At step 705, the system starts. At step 710, the system performs decision analysis and input using a decision making module (DMM) by uploading a design structure to a decision making module 210 through a computer aided design (CAD) software. At step 715, the system performs cost-benefit analysis and decision making by performing feasibility and efficiency of using the snake robot process versus 3D printing using a decision tree algorithm. In particular, the cost-benefit analysis and decision making is based on historical data and predictions of time, cost, and material usage.

At step 720, the system analyzes the design structure by a snake robot swarm system (SRSS). In embodiments, the snake robot swarm system (SRSS) is included in the snake robot swarm module 212. The system analyzes the design structure by utilizing a convolutional neural network (CNN) to interpret spatial patterns and design details of the design structure to determine a snake robot configuration. The system dynamically derives a formation, configuration, and a number of snake robots based on the snake robot configuration to form a mold. At step 725, the system utilizes the SRSS to command at least one snake robot to wrap around the design structure to form a mold. The system also utilizes long short-term memory (LSTM) networks to ensure dynamic and real-time feedback adjustments if discrepancies arise in the formation of the mold.

At step 730, the system utilizes the SRSS to communicate with a liquid pouring and monitoring module (LPMM) to signal initiation of pouring the liquid material into the formed mold to create a molded object. In embodiments, the LPMM is included in the liquid pouring and monitoring module 214. The LPMM regulates a flow rate and volume of the liquid material using a proportional integral derivative (PID) controller for consistency in filling the formed mold to create the molded object. At step 735, the system utilizes the LPMM to monitor and predict a material solidification state of the molded object. At step 740, the LPMM informs the SRSS to detach the at least one snake robot from the molded object in response to a predetermined solidification level being achieved. The at least one snake robot completely detaches from the molded object to free the molded object from the at least one snake robot. At step 745, the system utilizes the DMM to perform a final analysis using the CNNs to compare an actual output of the molded object with a desired design to ensure quality control. The system relays feedback to promote continuous system improvement.

In embodiments, a service provider could offer to perform the processes described herein. In this case, the service provider can create, maintain, deploy, support, etc., the computer infrastructure that performs the process steps of the present invention for one or more customers. These customers may be, for example, any business that uses technology. In return, the service provider can receive payment from the customer(s) under a subscription and/or fee agreement and/or the service provider can receive payment from the sale of advertising content to one or more third parties.

In still additional embodiments, the present invention provides a computer-implemented method, via a network. In this case, a computer infrastructure, such as computer 101 of FIG. 1, can be provided and one or more systems for performing the processes of the present invention can be obtained (e.g., created, purchased, used, modified, etc.) and deployed to the computer infrastructure. To this extent, the deployment of a system can comprise one or more of: (1) installing program code on a computing device, such as computer 101 of FIG. 1, from a computer readable medium; (2) adding one or more computing devices to the computer infrastructure; and (3) incorporating and/or modifying one or more existing systems of the computer infrastructure to enable the computer infrastructure to perform the processes of the present invention.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
determining that a snake robot is to be utilized based on performing a cost benefit analysis on a design structure using a trained artificial intelligence (AI) model;
determining spatial patterns and design details of the design structure based on analyzing the design structure by utilizing a first convolutional neural network (CNN) model;
dynamically determining a configuration mold based on the determined spatial patterns and the determined design details of the design structure;
creating a mold by commanding a snake robot to wrap around a physical representation of the design structure;
creating a molded object by performing pouring of liquid material into the created mold; and
commanding detachment of the snake robot from the molded object in response to a predetermined solidification level of the poured liquid material into the molded object being achieved.

2. The method of claim 1, further comprising receiving the design structure from an external application, wherein the external application comprises a computer aided design (CAD) which interprets and visualizes 3D structures.

3. The method of claim 1, wherein the trained AI model is trained using a decision tree algorithm.

4. The method of claim 1, wherein the trained AI model is trained using a particle swarm optimization algorithm.

5. The method of claim 1, wherein the trained AI model is trained using a gradient descent algorithm.

6. The method of claim 1, further comprising performing a final analysis of the molded object after detachment of the snake robot using a second CNN model.

7. The method of claim 6, wherein the second CNN model compares the molded object after detachment of the snake robot with a desired design to ensure quality control.

8. The method of claim 7, wherein the second CNN model is trained using historical designs.

9. The method of claim 1, wherein the configuration mold comprises a formation, a number of snake robots, a shape, a length, and a wrapping pattern.

10. The method of claim 9, wherein the wrapping pattern comprises a muti-layer wrapping pattern.

11. The method of claim 1, further comprising determining discrepancies between the created molded object and a predicted molded object using a long short-term memory (LSTM) model.

12. A computer program product comprising:
one or more computer readable storage media; and
program instructions stored on the one or more computer readable storage media to perform operations comprising:
receiving a design structure from an external application;
determining that a snake robot is utilized based on performing a cost benefit analysis on the design structure using a trained artificial intelligence (AI) model;
determining spatial patterns and design details of the design structure based on analyzing the design structure by utilizing a first convolutional neural network (CNN) model;
dynamically determining a configuration mold based on the determined spatial patterns and the determined design details of the design structure;
creating a mold by commanding the snake robot to wrap around a physical representation of the design structure;
creating a molded object by performing pouring of liquid material into the created mold; and
commanding detachment of the snake robot from the molded object in response to a predetermined solidification level of the poured liquid material into the molded object being achieved.

13. The computer program product of claim 12, wherein the external application comprises a computer aided design (CAD) which interprets and visualizes 3D structures.

14. The computer program product of claim 12, wherein the trained AI model is trained using a decision tree algorithm.

15. The computer program product of claim 12, wherein the trained AI model is trained using a particle swarm optimization algorithm.

16. The computer program product of claim 12, wherein the trained AI model is trained using a gradient descent algorithm.

17. The computer program product of claim 12, wherein the operations further comprise performing a final analysis of the molded object after detachment of the snake robot using a second CNN model.

18. The computer program product of claim 12, wherein the operations further comprise determining discrepancies between the created molded object and a predicted molded object using a long short-term memory (LSTM) model.

19. The computer program product of claim 12, wherein the configuration mold comprises a formation, a number of snake robots, a shape, a length, and a wrapping pattern.

20. A system comprising:
a processor set;
one or more computer readable storage media; and
program instructions stored on the one or more computer readable storage media to cause the processor set to perform operations comprising:
receiving a design structure from an external application;
determining that a snake robot is to be utilized based on performing a cost benefit analysis on the design structure using a trained artificial intelligence (AI) model;
determining spatial patterns and design details of the design structure based on analyzing the design structure by utilizing a first convolutional neural network (CNN) model;
dynamically determining a configuration mold based on the determined spatial patterns and the determined design details of the design structure;
creating a mold by commanding the snake robot to wrap around a physical representation of the design structure;
creating a molded object by performing pouring of liquid material into the created mold;
commanding detachment of the snake robot from the molded object in response to a predetermined solidification level of the poured liquid material into the molded object being achieved; and
performing a final analysis of the molded object after detachment of the snake robot using a second CNN model which is different from the first CNN model.
